(19) United States
(12) Patent Application Publication
(10) Pub. No.: US 2009/0219691 A1
(43) Pub. Date: Sep. 3, 2009

(54) Heat sink capable of internal deflection

(75) Inventor: Shih-Chih Lin, Taipei County (TW)

Correspondence Address: BACON & THOMAS, PLLC, 625 SLATERS LANE, FOURTH FLOOR, ALEXANDRIA, VA, 22314-1176, US

(73) Assignee: TAI-SOL ELECTRONICS CO., LTD., TAIPEI CITY (TW)

(21) Appl. No.: 12/081,062

(22) Filed: Apr. 10, 2008

(30) Foreign Application Priority Data
Mar. 3, 2008 (TW) 97203584

(51) Int. Cl. H05K 7/20

(52) U.S. Cl. 361/697

(57) ABSTRACT

A heat sink includes a heat-dissipating member and a cooling fan. The heat-dissipating member includes at least two spaced fins. Each of the two fins has a first side, a second side, and a deflection piece mounted to a surface thereof. Each of the deflection pieces is inclined, extending from the first side toward the second side and engaging the adjacent fin. The cooling fan is mounted to the heat-dissipating member and close to the first sides of the fins. Accordingly, the heat sink enlarges the heat-dissipating area and enhances the heat-dissipating efficiency on the whole.

### BACKGROUND OF THE INVENTION

1. Field of the Invention

The present invention relates generally to heat sinks, and more particularly, to a heat sink capable of internal deflection.

2. Description of the Related Art

General electronic components generate high heat in operation and if the temperature of the electronic components is too high, the electronic product having the overheated electronic components will fail to function normally. Thus, the general electronic product is provided with a heat sink for keeping the electronic components working in stable operating temperature.

A general heat sink includes a bottom plate, a fin set mounted to the bottom plate, and a cooling fan mounted to the fin set. The bottom plate is mounted to an electronic component in need of thermal dissipation, such that the heat generated from the electronic component can be transferred to the bottom plate and the fin set. When the cooling fan is operated, the airstream is generated to take the heat away from the fin set, thus thermally dissipating the electronic component.

However, the efficiency of thermal dissipation is required higher and higher and thus the above-mentioned heat sink becomes relatively larger and larger. When the heat sink is mounted to the electronic component in need of thermal dissipation, the heat sink structurally interferes the thermal dissipation of other electronic components located around this one and the heat sink, such that the whole heat-dissipating area becomes smaller and the efficiency of the thermal dissipation becomes lower.

### SUMMARY OF THE INVENTION

The primary objective of the present invention is to provide a heat sink capable of internal inflection, which produces relatively larger area of thermal dissipation to have relatively higher heat-dissipating efficiency on the whole.

The foregoing objective of the present invention is attained by the heat sink, which is composed of a heat-dissipating member and a cooling fan. The heat-dissipating member includes at least two spaced fins. Each of the two fins has a first side, a second side, and a deflection piece mounted to a surface thereof. Each of the deflection pieces is inclined, extending from the first side toward the second side and engaging the adjacent fin. The cooling fan is mounted to the heat-dissipating member and close to the first sides of the fins.

### BRIEF DESCRIPTION OF THE DRAWINGS

FIG. 1 is an exploded view of a preferred embodiment of the present invention.

FIG. 2 is an elevation view of the preferred embodiment of the present invention.

FIG. 3 is a right view of the preferred embodiment of the present invention.

FIG. 4 is a left view of the preferred embodiment of the present invention.

FIG. 5 is a rear view of the preferred embodiment of the present invention.

FIG. 6 is a side view of a part of the preferred embodiment of the present invention, illustrating the structure of the fins.

FIG. 7 is a rear view of a part of the preferred embodiment of the present invention, illustrating the structure of the fins.

### DETAILED DESCRIPTION OF PREFERRED EMBODIMENTS

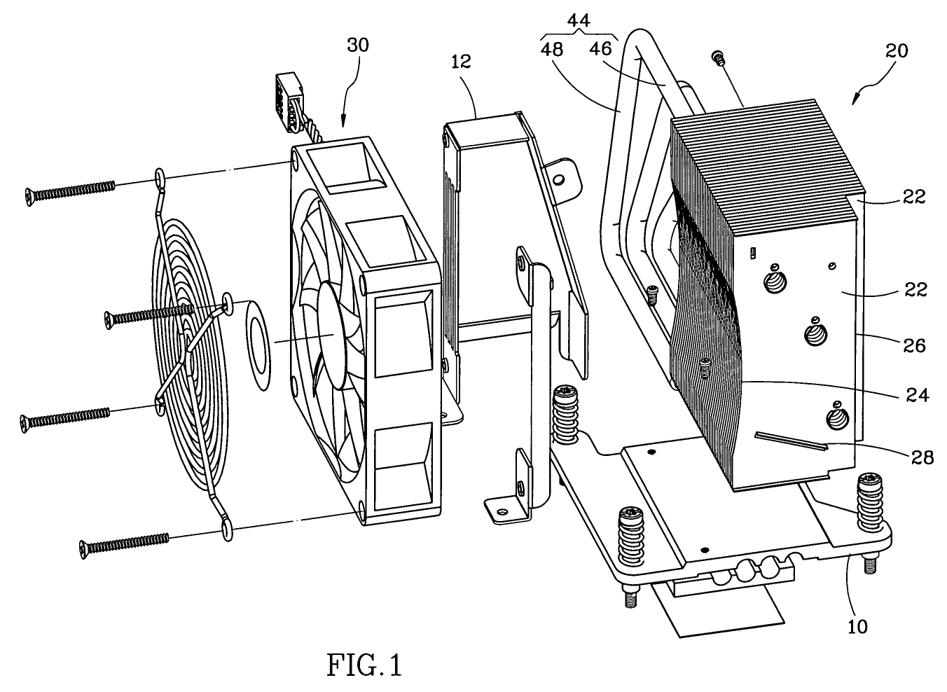

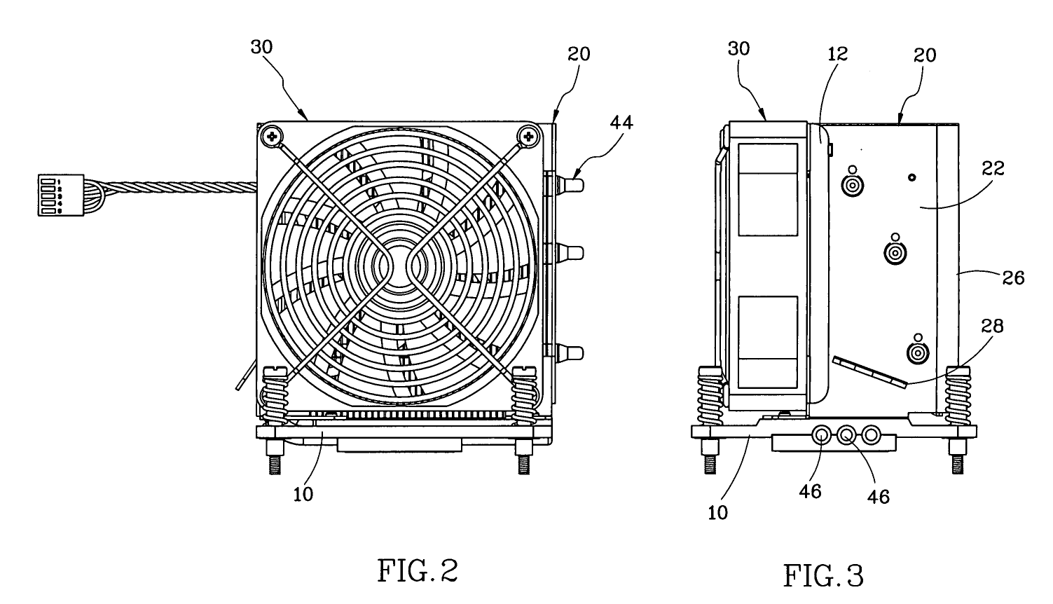

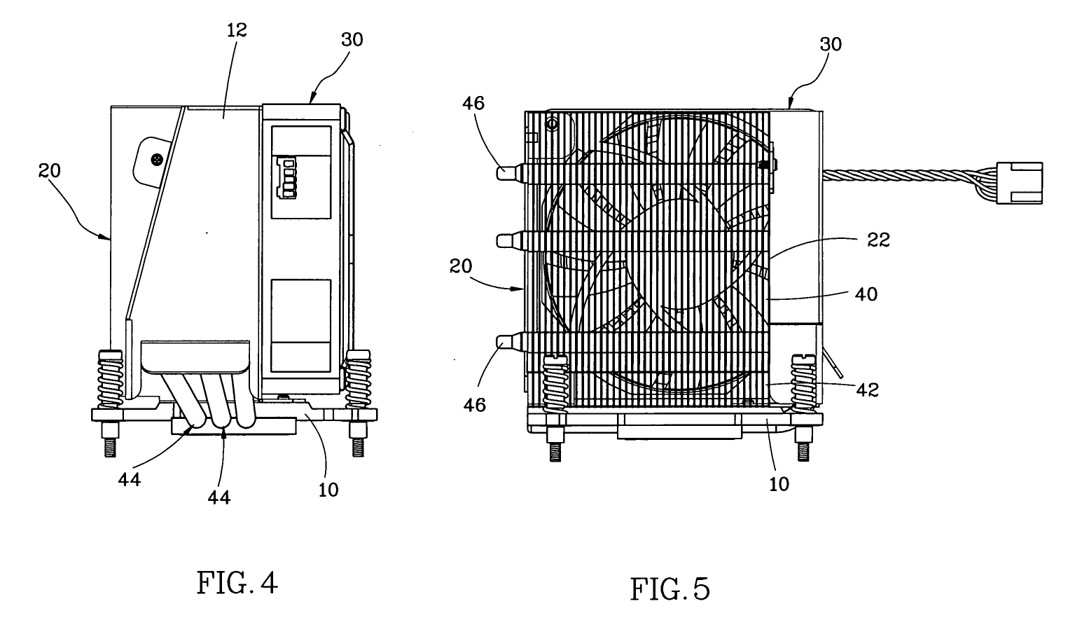

Referring to FIGS. 1-5, a heat sink capable of internal deflection constructed in accordance with a preferred embodiment of the present invention is composed of a bottom plate 10, a heat-dissipating member 20, and a cooling fan 30. Each of the bottom plate 10 and the heat-dissipating member 20 is made of heat-conductive material. The heat-dissipating member 20 includes a plurality of fins 22 parallel spaced from one another. The heat-dissipating member 20 is mounted to the bottom plate 10 via a strut 12.

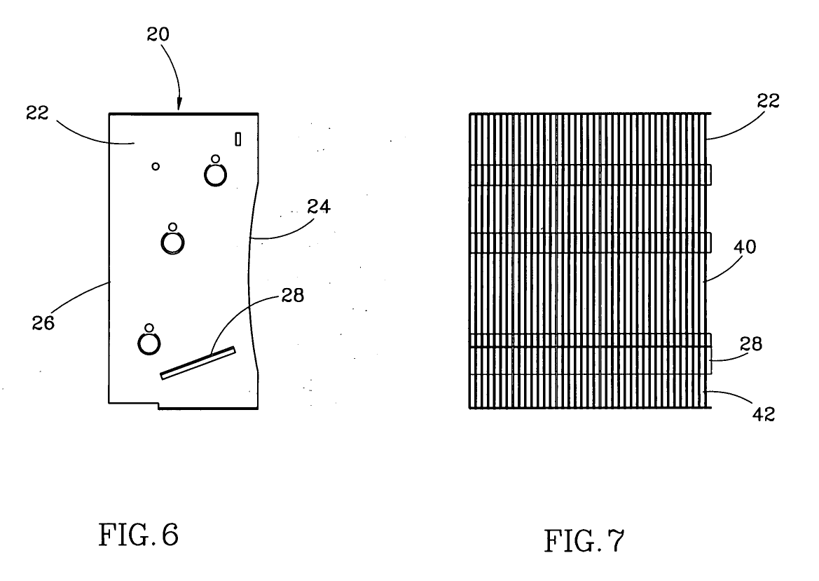

Referring to FIGS. 6 and 7, each of the fins 22 includes a first side 24, a second side 26 opposite to the first side 24, and a deflection piece 28 mounted vertically to a surface thereof. Each of the deflection pieces 28 is inclined, extending downward from the first side 24 toward the second side 26. Each of the deflection pieces 28 engages a surface of the adjacent fin 22 to define, between each two adjacent fins, an upper space 40 and a lower space 42.

The cooling fan 30 is mounted to the strut 12 and abuts the first sides 24 of the fins 22, for generating and driving the airstream to pass through the fins 22 and to exit from the second sides 26. The heat-dissipating member 20 further includes three heat pipes 44. Each of the heat pipes 44 has two penetrative sections 46 and an intermediate section 48 located between the two penetrative sections 46. In each of the heat pipes 44, one of the two penetrative sections 46 runs through the fins 22, the other runs through the bottom plate 10, and the intermediate section 48 is located outside the fins 20. In light of this, the heat pipes 44 can increase the efficiency of thermal dissipation of the heat sink on the whole.

When the heat sink of the present invention is mounted to an electronic component for thermal dissipation, the cooling fan 30 is operated to generate airstream and then the airstream flows into what is between each two adjacent fins 22, flowing inside the upper spaces 40 and the lower spaces 42. The air stream flowing through the upper spaces 40 flows parallel out of the heat-dissipating member 20 to exhaust the high heat generated by the electronic component in operation. The airstream flowing through the lower spaces 42 is interfered by the inflection pieces 28 to flow toward lower sides of the fins 22. In this way, the airstream not only dissipates the heat of the electronic component but also flows toward other electronic components around the heat sink to also take the heat generated by those electronic components in operation to the external environment for thermal dissipation.

Therefore, the present invention can enlarge the area of thermal dissipation and increase the efficiency of thermal dissipation on the whole.

Although the present invention has been described with respect to a specific preferred embodiment thereof, it is no way limited to the details of the illustrated structures but changes and modifications may be made within the scope of the appended claims.

What is claimed is:

1. A heat sink capable of internal deflection, comprising:
a heat-dissipating member having at least two spaced fins, each of said at least two fins having a first side, a second side, and a deflection piece located on a surface thereof, each of said deflection pieces being inclined and extending from said first side toward said second side and engaging the adjacent fin; and
a cooling fan mounted to said heat-dissipating member and abutting said first sides of said fins.

2. The heat sink as defined in claim 1, wherein each of said deflection pieces is inclined downward from said first side toward said second side.

3. The heat sink as defined in claim 1 further comprising a bottom plate, wherein said heat-dissipating member is mounted to said bottom plate.

4. The heat sink as defined in claim 3 further comprising at least one heat pipe, wherein each of said at least one heat pipe includes two penetrative sections and an intermediate section located between said penetrative sections, one of said two penetrative sections runs through said heat-dissipating member and the other runs through said bottom plate.
